(19) United States
(12) Patent Application Publication
(10) Pub. No.: US 2011/0294276 A1
(43) Pub. Date: Dec. 1, 2011

(54) Method of manufacturing semiconductor device

(75) Inventor: Keiji Kuroki, Tokyo (JP)

(73) Assignee: ELPIDA MEMORY, INC., Tokyo (JP)

(21) Appl. No.: 13/067,286

(22) Filed: May 20, 2011

(30) Foreign Application Priority Data
May 27, 2010 (JP) 2010-121636

(51) Int. Cl. H01L 21/20

(52) U.S. Cl. 438/381; 257/E21.09

(57) ABSTRACT

SiOC film (124) of a low-k film is interleaved in a region where bowing occurs when forming a contact hole in SiO₂ film (123, 125), thereby forming a stacked structure, and in dry etching, an etching rate of SiOC film (124) is selected to be slower 1/5 to 1/10 times the etching rate of SiO₂ film, thereby restricting the bowing.

### BACKGROUND OF THE INVENTION

1. Field of the Invention

The present invention relates, in general, to a method of manufacturing a semiconductor device, more particularly, to a semiconductor device in which a high aspect ratio hole is formed, and a method of manufacturing the same.

2. Description of the Related Art

In a semiconductor device, a high aspect ratio contact (HARC) dry etching technique is used for example to form a contact hole for interconnecting an upper layer and a lower layer.

Recently, in order to improve capacitance of a capacitor, a semiconductor memory device such as DRAM is configured so that a lower electrode thereof is made into a cylindrical shape with a 3D structure, and the height of the electrode is elevated to increase a surface area thereof. Such a cylindrical electrode is formed in such a manner that a deep hole is formed in an insulating film that is a profile shape material, such as silicon dioxide (SiO₂), by HARC dry etching, and a conductive film is formed in the deep hole. However, if an aspect ratio (a ratio of diameter to depth) increases with the miniaturization of the device, the shape of the etched deep hole suffers from shape deformation called bowing. It is known that if the aspect ratio exceeds 15 or more, the shape due to bowing becomes considerably worse.

The problem of bowing will be described with reference to FIG. 7.

FIG. 7A: Plug 202 is formed in a contact hole of second interlayer insulating film 201 on a semiconductor substrate, and silicon nitride film 203 serving as an etching stopper and third interlayer insulating film 204 formed of 3 μm silicon dioxide film are formed. Next, 0.5 μm amorphous silicon film is formed by a CVD process, and hard mask 205 having an opening diameter of 0.2 μm is formed by photo-lithography and dry etching.

FIG. 7B: It is shown that third interlayer insulating film 204 is etched by about 1 μm, under the condition that etching gas is mainly C₅F₈ and O₂ (Ar, CHF₃, or the like may be added thereto), pressure is 13.3 Pa (100 mTorr), and plasma power is 1200 W. The shoulder part of the hard mask 205 is first etched and starts to dip. In this stage, the hole is substantially vertical and the bowing does not occur.

FIG. 7C: It is shown that the etching is further performed and third interlayer insulating film 204 is etched up to about 2 μm. Here, the shoulder of hard mask 205 is further removed and the slope area at the shoulder of hard mask 205 is enlarged so as to generate the bowing 206. The dry etching of the silicon dioxide film is carried out by breaking Si—O bond in the silicon dioxide film using ions generated in plasma and reacting F and Si to produce SiF₄, which is volatilized and removed. A primary etchant contributing to etching is F ions. While F ions are accelerated basically vertically to the substrate by electric potential difference between plasma and the substrate, which is induced by plasma self-bias or forcedly applied bias, as the etching proceeds, some ions are rebounded at the slope generated at the shoulder of hard mask 205 and increasingly advance obliquely. It is assumed that the bowing occurs because the rebounded F ions etch the sidewall of the silicon dioxide film near the opening of the etched hole. This phenomenon does not cause a problem at a relatively shallow hole (e.g. the hole having the depth, the magnitude of which has the level shown in FIG. 7B) as adapted in the related art, but it becomes severe as the hole is made narrower and deeper in order to miniaturize a device and secure capacitance of the device as a capacitor.

FIG. 7D: It is shown that etching of the deep hole is completed so that plug 202 is exposed therein. Due to bowing, a minimum width L2 of a partition wall between adjacent holes is shorter than that of the dimension L1 (design size) of the mask.

FIG. 7E: It is shown that polysilicon 207 of 40 nm, which serves as a lower electrode, is formed by CVD process.

FIG. 7F: It is shown that after the inside of the deep hole is filled with infill 208 such as photoresist, the polysilicon 207 exposed to the outside at a position other than the hole is removed. For removal of the polysilicon, chemical mechanical polishing (CMP) or dry etching may be used. The dry etching is carried out for example under the condition that primary etching gas is Cl₂ and O₂ (HBr may be added thereto), pressure is 1.3 Pa (10 mTorr), and plasma power is 100 W.

FIG. 7G: It is shown that the infill 208 in the deep hole is removed by a method such as an oxygen plasma technique. In this stage, a capacitor may be formed by forming hemispherical grains (HSGs) and then a capacitor dielectric and an upper electrode. In case of preparing the HSGs, a silicon film is required to be of not a polycrystalline state, but an amorphous state.

FIG. 7H: It is shown that third interlayer insulating film 204 around the deep hole is etched and removed in order to increase a surface area of the electrode.

FIG. 7I: It is shown that capacitor dielectric 209 is formed by CVD process.

FIG. 7J: It is shown that upper electrode 210 made of titanium nitride is formed by CVD process to complete the capacitor. Here, because of the bowing occurring upon forming the deep hole, a plurality of voids is formed in the outside and inside of the deep hole.

In the above-mentioned related art, because of the bowing phenomenon that essentially occurs as the hole is formed deeper by anisotropic dry etching, the minimum width L2 of the partition wall in the hole becomes smaller than the design dimension L1, so that tolerance margin should be set to be larger, making it difficult to perform miniaturization.

Further, if the interlayer insulating film around the lower electrode is removed in order to obtain higher capacitance of a capacitor, the lower electrode has no vertical sidewall to the substrate plane, so that even though the upper electrode is formed until an upper opening of the lower electrode is blocked, many voids are generated outside and inside the lower electrode, thereby being considerably vulnerable to mechanical stress (see FIG. 7J). Specifically, it is readily affected by the stress of the upper electrode itself constituting the capacitor, the stress of insulating films in the process of the formation of an interconnect after the formation of the capacitor, the stress by mold resin upon assembly to a package, or the like. Thus, though in the quality test, the capacitor just after formed has a good characteristic, in the test performed after the assembly into the package, but before shipping, the characteristic decreases so that the yield is considerably reduced.

To solve this bowing phenomenon, JP 2002-110647A proposed a HARC dry etching method which is carried out in a multi-step such that an etching condition (e.g., in an etchant atmosphere containing oxygen) suitable for weak deposition is applied to a portion where the bowing occurs, and an etching condition suitable for strong deposition is applied to the deep portion of the hole, thereby restricting the bowing. Further, JP 2004-3355256A proposed a method in which with respect to the HARC etching, the dry etching of the silicon dioxide film is once stopped at the depth where the bowing does not occur, and a film (e.g. silicon nitride film), an etching rate of which is slower than that of the silicon dioxide film, is used as a protective film of a sidewall, thereby forming a deeper contact hole.

Meanwhile, JP 2002-43437A proposed a method in which upper and lower silicon dioxide films are configured such that the lower silicon dioxide film has the etching rate faster than that of the upper silicon dioxide film, particularly the upper film being formed from a conventional plasma oxide film and the lower film being formed from a BPSG film, so that the silicon dioxide film having the thickness of 2.6 μm or 3.6 μm is provided with a storage node hole with little variation between the upper width and the lower width.

The method disclosed in JP 2002-110647A is a method in which the dry etching condition for forming the deep hole is finely controlled so that the plasma state is changed, and the state is alternately repeated by condition control using etching characteristics of plasma and deposition characteristics of an organic substance, thereby restricting the bowing. However, this method has a problem in that it is in fact difficult to control the plasma state in the deep hole, so that the formation of the deep hole, which is a primary purpose to accomplish, may be infeasible. Particularly, a phenomenon so called etch stop occurs that in a deep hole having a high aspect ratio, the etching depth cannot reach desired depth. Further, since the method disclosed in JP 2002-43437A is proposed to solve the problem of the shape of the hole being sharpened due to the deposition of deposit occurring upon slope etching, it cannot sufficiently deal with the problem of bowing occurring due to the effect of the rebounded F ions or the like.

Like this, the conventional methods cause problems such as the bowing phenomenon occurring when forming the deep hole such as a high aspect ratio cylinder hole or contact hole or the like using dry etching, short circuit occurring between conductors formed in adjacent holes, coverage defects in forming a conductive film in the hole, or the like.

### SUMMARY

In an aspect of the present invention, a method of manufacturing a semiconductor device is provided which is capable of restricting a bowing phenomenon in the formation of a hole having a high aspect ratio. In an aspect of the present invention, when a deep hole is formed in a silicon dioxide film, a low dielectric insulating film called a low-k film is inserted at a position where bowing occurs, forming a stacked structure.

In an embodiment of the present invention, a method of manufacturing a semiconductor device includes forming a deep hole in an insulating film on a semiconductor substrate using dry etching, wherein the insulating film has a stacked structure in which a low dielectric insulating film is interleaved in a silicon dioxide film, the low dielectric insulating film being of etching characteristics different from those of the silicon dioxide film, wherein the low dielectric insulating film is interleaved in a region where bowing occurs when the deep hole is formed only in the silicon dioxide film using the dry etching carried out in a prescribed condition, and wherein upon the etching of the silicon dioxide film in the prescribed condition, an etching rate of the low dielectric insulating film is slower than that of the silicon dioxide film.

With the restriction of the bowing phenomenon in the HARC dry etching which is carried out for example to form a cylinder hole for an electrode, problems of short circuit between adjacent cylindrical electrodes, electrode film-forming trouble in the cylinder hole, or the like can be prevented.

### BRIEF DESCRIPTION OF THE DRAWINGS

The above features and advantages of the present invention will be more apparent from the following description of prescribed preferred embodiments taken in conjunction with the accompanying drawings, in which:

FIGS. 1A to 1E are cross-sectional views explaining a procedure of forming a high aspect ratio hole according to an embodiment of the present invention.

FIG. 2 is a conceptual view explaining the position where a low dielectric insulating film is interleaved.

FIG. 3 is a schematic view showing the construction of a semiconductor device according to an embodiment of the present invention.

FIGS. 4A to 4D are cross-sectional views explaining a procedure of manufacturing a capacitor according to an embodiment of the present invention.

FIG. 5 is a schematic cross-sectional view showing the construction of a semiconductor device according to another embodiment of the present invention.

FIGS. 6A to 6D are cross-sectional views explaining a procedure of manufacturing a capacitor according to another embodiment of the present invention.

FIGS. 7A to 7J are cross-sectional views explaining a solution of the related art.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

The present invention is provided to restrict a bowing phenomenon when forming a high aspect ratio hole (deep hole). Specifically, the present invention can be adapted to a formation of a cylinder hole for a capacitor, which serves as a memory element of DRAM device, or a formation of a contact hole which connects between lower and upper interconnects after the formation of the capacitor.

A low dielectric (low-k) insulating film means an insulating film that has lower relative dielectric than that of silicon dioxide having a range of 3.8 to 4.3. Specifically, the low dielectric insulating film may use an organic silica glass-based or organic polymeric film, a SiOF-based film, a porous organic polymeric film, or the like. Particularly, the present invention employs an organic silica glass-based silicon oxycarbide (SiOC) having the relative dielectric constant of 3.0 to 3.2, which is formed by a CVD process and such SiOC film is interleaved at a position where bowing occurs when a silicon dioxide film is solely formed and dry-etched in a prescribed condition. In the dry etching of the silicon dioxide film below the low dielectric insulating film in the prescribed condition, the condition is selected such that the etching rate of the low dielectric insulating film is slower than that of the silicon dioxide film, thereby suppressing the bowing. Particularly, the etching rate of the SiOC film can be controlled to be slower such that it corresponds to ⅕ to 1/10 times the etching rate of the silicon dioxide film.

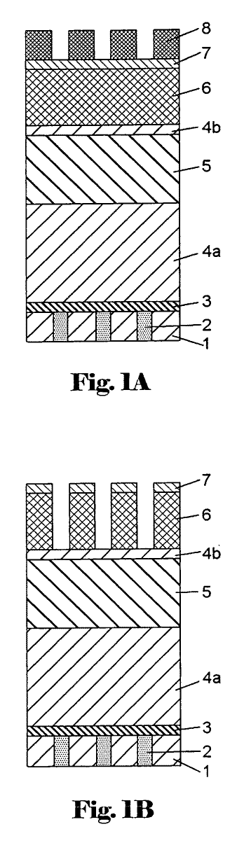

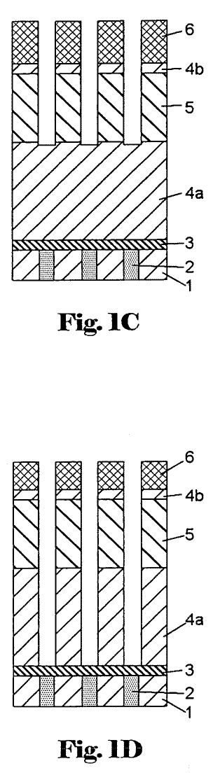

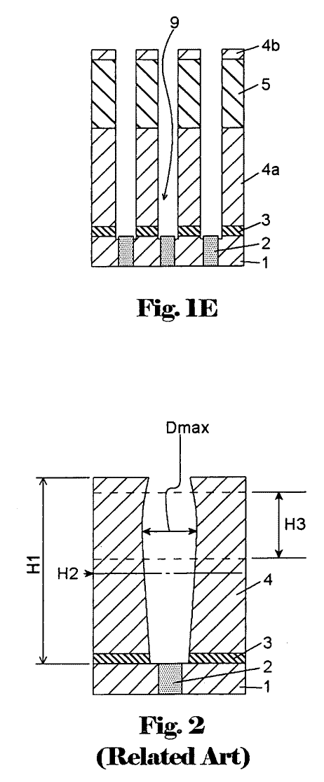

An exemplary embodiment of the present invention will be described in detail with reference to FIG. 1.

First, as shown in FIG. 1A, plug 2 is formed on insulating film 1, and silicon nitride film 3 is formed thereon. Silicon nitride (SiN) film 3 serves as a stopper against dry etching by which a cylinder hole is formed. In addition, lower silicon dioxide film 4a, SiOC film 5, and upper silicon dioxide film 4b are stacked to form a cylinder core layer in which the cylinder hole is to be formed. The upper silicon dioxide film 4b serves to prevent the low-k film from being damaged because when amorphous carbon film 6, which serves as a mask against the dry etching of the cylinder core layer, is etched using O₂-based etching gas, if SiOC film 5 exposes on top surface, the film quality may be problematically varied. Further, SiOC film 5 is interleaved into a region where bowing occurs when the cylinder core layer solely formed with silicon dioxide film is dry-etched in a prescribed condition.

The region where the bowing occurs can be easily known by performing a preliminary dry etching. For example, as shown in FIG. 2, when silicon dioxide film 4 is solely formed on SiN film 3 and is etched, a hole having a bowing profile is formed. Here, a maximum diameter Dₘₐₓ of the hole is located above the half depth (H2) of the hole depth H1. The interleaving position of SiOC film is located in a region H3 that is above the half depth H2 and includes the region of Dₘₐₓ. The thickness of the region H3 may have a range allowing the bowing to be sufficiently prevented. The depth preferably has a range of more than ⅕ to less than ½ of the hole depth H1 around the region of Dₘₐₓ. In the example of FIG. 1, a structure is shown in which lower silicon dioxide film 4a of 1 μm thickness, SiOC film 5 of 700 nm thickness, and upper silicon dioxide film 4b of 100 nm thickness are stacked on SiN film 3 of 100 nm thickness (the hole depth is 1.9 μm).

After amorphous carbon film 6 and anti-reflection layer (ARL) 7 against lithography are formed, resister pattern 8 is formed by performing the lithography. Here, a hole pattern having an aperture diameter of 80 nm is formed.

Next, a shown in FIG. 1B, etching of ARL (SiO₂/SiON) 7 using resister pattern 8 as a mask and etching of amorphous carbon film 6 using a mask of ARL (SiO₂/SiON) 7 are performed to form a mask used in dry etching of the cylinder hole.

The cylinder hole is formed by two steps including dry etching of upper silicon dioxide film 4b and SiOC film 5 shown in FIG. 1C, and dry etching of silicon dioxide film 4a shown in FIG. 1D.

In the dry etching of SiOC film 5, the etching rate of SiOC film 5 is slower than that of the silicon dioxide film in a conventional SiO₂ etching condition. To accelerate the etching of SiOC film 5 until the etching rate of SiOC film 5 becomes equal to that of SiO₂ film, at least one of CHF₃ gas and CH₂F₂ gas can be added to the atmosphere commonly used for the conventional SiO₂ etching.

For example, such an etching condition can be the following condition.

Pressure: about 6.7 Pa (50 mTorr)

RF power: 1000 W (60 MHz)/2000 W (2 MHz)

Etching gas: C₄F₈/CH₂F₂/N₂/Ar=10/20/50/500 sccm.

Next, as shown in FIG. 1D, lower silicon dioxide film 4a is dry etched in the afore-mentioned prescribed etching condition. In such an etching condition, SiOC film 5 has higher selectivity than silicon dioxide film 4. For example, if the following etching condition is selected, the etching rate of SiOC film 5 is restricted to the range of ⅕ to 1/10 of the etching rate of lower silicon dioxide film 4a.

Pressure: about 13.3 Pa (100 mTorr)

RF power: 2000 W (60 MHz)/2500 W (2 MHz)

Etching gas: C₄F₆/O₂/Ar=20/10/800 sccm.

Next, etching of SiN film 3 and removal of amorphous carbon film 6 are performed to form a cylinder hole without bowing as shown in FIG. 1E.

According to the embodiment, since the silicon oxycarbide film (SiOC film) having lower dry etching rate is formed in a region near the depth where the bowing occurs, lateral etching is restricted so that a cylinder hole having a substantially vertical sidewall without bowing can be formed. Thus, problems of short between adjacent cylinders, defects in film-forming in the cylinder of the electrode, or the like can be prevented.

In case of a contact hole (or through hole), the contact hole (or through hole) is formed by replacing plug 2 shown in FIG. 1 with a conductive film such as an interconnect layer or the like.

(Application Example 1)

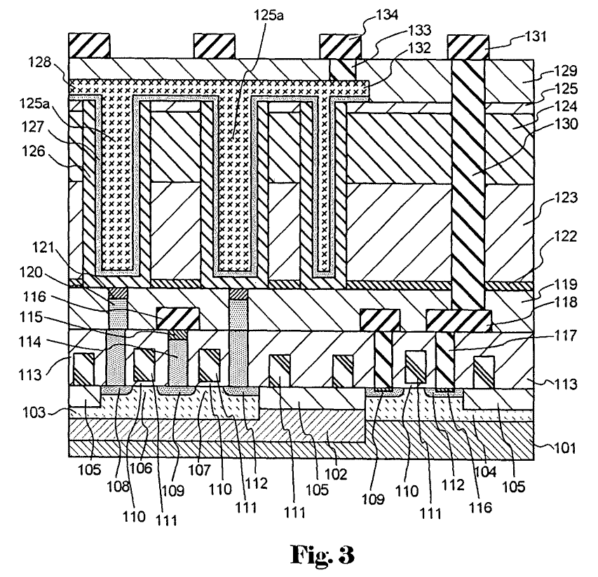

Next, the entire construction of a DRAM according to one embodiment of the present invention will be described with reference to a schematic cross-sectional view of FIG. 3. In this Example, a description will be made of a cylindrical capacitor that only uses an inner surface of a lower electrode formed in a deep hole as a capacitor.

n-Type well 102 in which first p-type well 103 is formed is formed in p-type silicon substrate 101. In addition, second p-type well 104 is formed in a region other than n-type well 102, in a state of being isolated by shallow trench isolation (STI) regions 105. For convenience, first p-type well 103 is shown in a memory array area in which a plurality of memory cells is arranged, and second p-type well 104 is shown in a peripheral circuit area.

In first p-type well 103, switching transistors 106 and 107 are formed which have a gate serving as a word line as an element of respective memory cell. Transistor 106 includes drain 108, source 109, and gate electrode 111 with gate insulating film 110 interposed. Gate electrode 111 has a polycide structure in which tungsten silicide is stacked on polysilicon, or a polymetal structure in which tungsten is stacked on polysilicon. Transistor 107 includes common source 109, drain 112, and a gate electrode 111 with a gate insulating film 110 interposed. The transistor is covered with first interlayer insulating 113 formed from a silicon dioxide film.

A contact hole is formed in a prescribed region of first interlayer insulating film 113 such that it is connected to source 109, the contact hole is filled with polysilicon, barrier film 115 formed of metal silicide, including titanium, cobalt, or the like, and titanium nitride is formed thereon, and bit line 116 formed of tungsten nitride and tungsten is formed such that it is connected to barrier film 115. Bit line 116 is covered with second interlayer insulating film 119 composed of a silicon dioxide film.

Contact holes are formed in prescribed regions of first and second interlayer insulating films 113 and 119 such that they are connected to drains 108 and 112, respectively, the contact holes are filled with silicon to form silicon plug 120 serving as a capacitor contact plug, and metal silicide film 121 formed of titanium, cobalt or the like is formed thereon.

A capacitor is formed such that it is connected to metal silicide film 121. Here, first, on second interlayer insulating film 119, sequentially formed are third interlayer insulating film 122 formed from silicon nitride serving as an etching stopper, fourth interlayer insulating film 123 formed from silicon dioxide, fifth interlayer insulating film 124 formed from silicon oxycarbide (SiOC) serving as an anti-bowing layer, and sixth interlayer insulating film 125 formed from silicon dioxide serving as a protection of fifth interlayer insulating film 124 formed from silicon oxycarbide. The sixth, fifth, fourth, third interlayer insulating films 125, 124, 123, and 122 are sequentially dry-etched to form cylinder hole 125a that exposes the upper surface of barrier film 121 of the capacitor contact plug. Lower electrode 126 is formed on an inner surface of cylinder hole 125a such that it is connected to the upper surface of barrier film 121. Capacitor dielectric 127 is formed on the entire surface of the memory cell area including the surface of lower electrode 126. In addition, upper electrode 128 is formed on the memory cell area while covering the surface of capacitor dielectric 127. Capacitors are formed by lower electrode 126, capacitor dielectric 127, and upper electrode 128 such that they correspond to the respective memory cells.

Lower electrode 126 uses metal or metallic compound such as ruthenium (Ru) or titanium nitride (TiN). Capacitor dielectric 127 uses a single- or multi-layer made of a high dielectric material such as aluminum oxide, hafnium oxide, zirconium oxide, tantalum oxide, and strontium titanate (STO). The upper electrode uses a stacked film of metal or metallic compound such as ruthenium, titanium nitride, and tungsten. The capacitor is covered with seventh interlayer insulating film 129.

Meanwhile, a transistor constituting a peripheral circuit is formed in second p-type well 104, wherein the transistor includes source 109, drain 112, gate insulating film 110, and gate electrode 111. Contact holes are formed in prescribed regions of first interlayer insulating film 113 such that they are connected to drain 112, metal silicide films 116 are formed on the surfaces of source 109 and drain 112 exposed to the bottom of the contact holes, and the contact holes are filled with titanium nitride and tungsten to form contact plugs 117. In addition, first interconnect layer 118 formed of tungsten nitride and tungsten is formed thereon. A portion of first interconnect layer 118 pass through the second to seventh interlayer insulating films 119, 122, 123, 124, 125, and 129 to form a though hole. Further, second interconnect layer 131 formed of titanium nitride, aluminum, and titanium nitride is formed thereon such that it is connected to via plug 130 formed of titanium and tungsten which fills the through hole. Further, upper electrode 128 of the capacitor formed in the memory cell area is drawn out, at its partial region, to the peripheral circuit area via lead wire 132, and is also connected to second interconnect layer 134 through via plug 133 formed of titanium tungsten and tungsten which fills the through hole formed in a prescribed region of seventh interlayer insulating film 129. Subsequently, if needed, the formation of the interlayer insulating film, the formation of contacts, and formation of interconnect layers are repeated to form a DRAM.

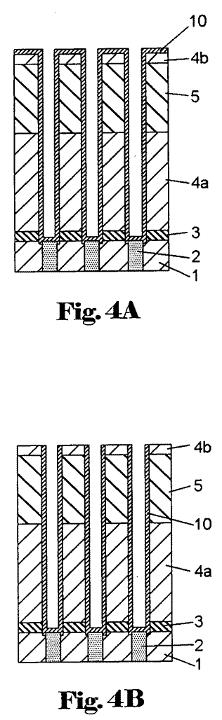

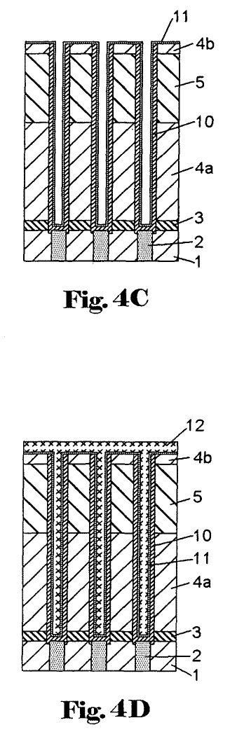

A procedure of forming a capacitor, followed by the procedure of FIG. 1, is shown in FIG. 4.

First, TiN film 10 of 20 nm thickness serving as a lower electrode is formed in cylinder hole 9, which is formed in step shown in FIG. 1E, by means of a CVD process (FIG. 4A).

Cylinder hole 9 is filled with an infill (not shown) such as photoresist, TiN film 10 exposed to the surface other than the hole is removed (FIG. 4B), and capacitor dielectric 11 is formed by means of a CVD process (FIG. 4C).

Finally, upper electrode 12 formed of TiN is formed by means of a CVD process, thereby forming a capacitor (FIG. 4D).

(Application Example 2)

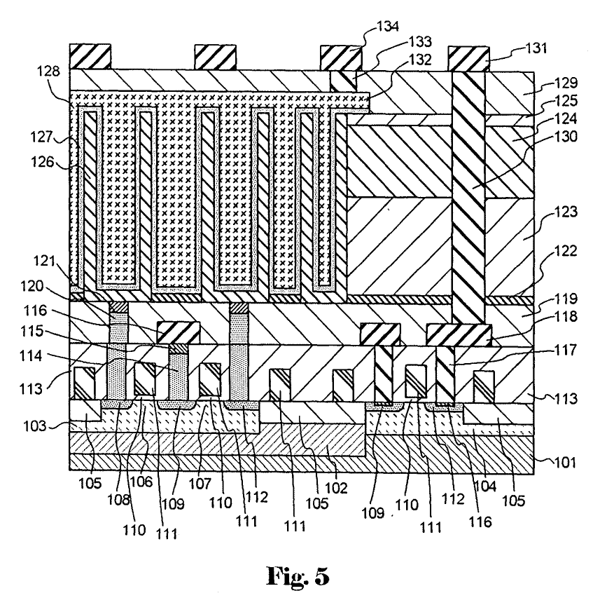

In this example, a description is made of a crown type capacitor structure which uses inner and outer walls of the lower electrode as a capacitor with reference to FIG. 5. Since only a capacitor structure is different from Application Example 1, only the capacitor structure will be described hereinafter.

As shown in FIG. 5, similarly to Application Example 1, capacitor contact plug 120 having metal silicide film 121 thereon is formed. Next, on second interlayer insulating film 119, sequentially formed are third interlayer insulating film 122 formed from silicon nitride serving as an etching stopper, fourth interlayer insulating film 123 formed from silicon dioxide, fifth interlayer insulating film 124 formed from silicon oxycarbide (SiOC) serving as an anti-bowing, and sixth interlayer insulating film 125 formed from silicon dioxide serving as a protection film of fifth interlayer insulating film 124 formed from silicon oxycarbide. The sixth, fifth, fourth, third interlayer insulating films, 125, 124, 123, and 122 are sequentially dry-etched to form cylinder hole 125a that exposes the upper surface of barrier film 121 of the capacitor contact plug. Lower electrode 126 is formed on an inner surface of cylinder hole 125a such that it is connected to the upper surface of barrier film 121.

Next, the sixth, fifth, and fourth insulating films 125, 124, and 123, which exist around the lower electrode 126, are serially removed by means of wet-etching using an etching solution containing hydrofluoric acid (HF). Here, a protection film such as photoresist is formed to cover the peripheral circuit region including the inside of a guard ring groove surrounding the memory cell area in order to prevent the sixth, fifth, and fourth interlayer insulating films 125, 124, and 123 formed in the peripheral circuit region, from being etched. With the wet-etching, the sixth, fifth, and fourth interlayer insulating films 125, 124, and 123, which were formed around lower electrode 126, are removed. Interlayer insulating film 122 remains as an etching stopper.

Subsequently, capacitor dielectric 127 is formed on the entire surface of the memory cell area including the surface of lower electrode 126. In addition, upper electrode 128 is formed on the whole of the memory cell area while covering the surface of capacitor dielectric 127. Capacitors are formed by lower electrode 126, capacitor dielectric 127, and upper electrode 128 such that they correspond to the respective memory cells.

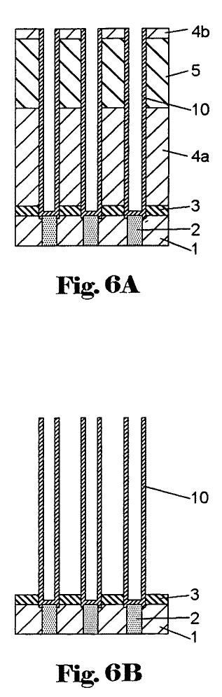

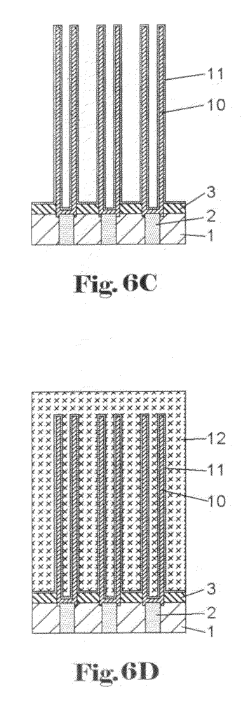

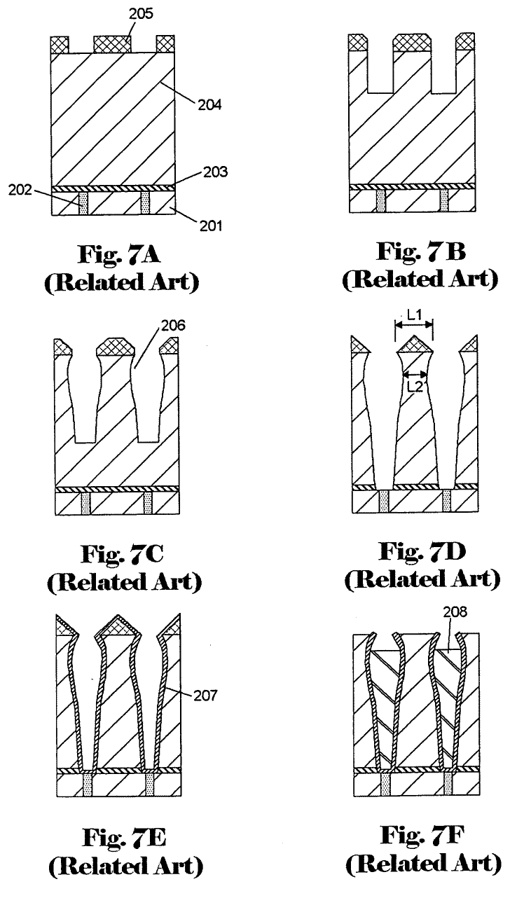

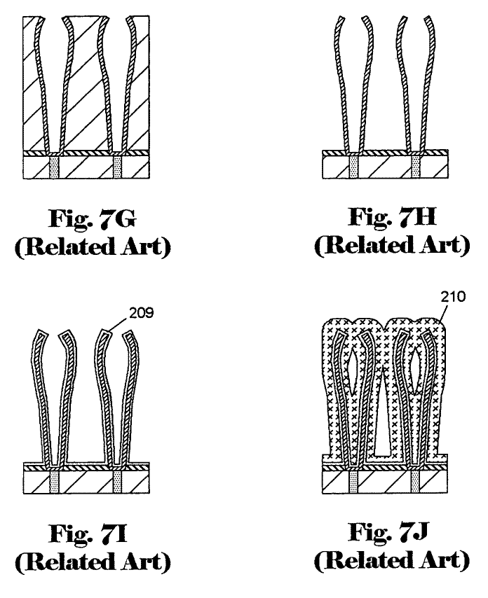

A procedure of forming a capacitor, followed by the procedure of FIG. 1, is shown in FIG. 6.

First, TiN film 10 of 20 nm thickness serving as a lower electrode is formed in cylinder hole 9, which is formed in step shown in FIG. 1E, by means of a CVD process (FIG. 6A).

Next, upper silicon dioxide film 4b, SiOC film 5, lower silicon dioxide film 4a are sequentially removed by means of wet-etching using an etching solution containing hydrofluoric acid (HF) (FIG. 6B).

Capacitor dielectric 11 is formed by means of a CVD process (FIG. 6C).

Finally, upper electrode 12 formed of TiN is formed by means of a CVD process, thereby forming a capacitor (FIG. 6D).

According to the present embodiment, since the cylinder hole is formed by restricting the occurrence of bowing, though the crown type capacitor structure which uses the inner and outer walls of the lower electrode is configured, voids do not created inside and outside of the lower electrode, and higher capacitance which amounts about two times that of Application Example 1 can be obtained while still maintaining the mechanical strength. In addition, the multi-layer stacked structure including the low dielectric insulating film is left in the peripheral circuit area as an interlayer insulating film, so that the bowing phenomenon can be restricted when forming the deep contact hole, which connects between the lower interconnect (a gate interconnect) and the upper interconnect (an aluminum interconnect), after the formation of the capacitor.

The present invention also relates to the following embodiments:

I. A semiconductor device comprising:

a memory array area in which a capacitor is formed;

a peripheral circuit area in which a peripheral circuit is formed,

wherein in at least the peripheral circuit area, a stacked structure in which a low dielectric insulating film is interleaved in a silicon dioxide film is provided as an interlayer insulating film having the same height as the capacitor, wherein the low dielectric insulating film has an etching characteristic different from that of the silicon dioxide film.

II. The semiconductor device of I, wherein the interlayer insulating film of the stacked structure is provided around the capacitor in the memory array area.

III. The semiconductor device of I or II, wherein the low dielectric insulating film is formed from a silicon oxycarbide film.

What is claimed is:

1. A method of manufacturing a semiconductor device comprising:
forming a deep hole in an insulating film on a semiconductor substrate using dry etching,
wherein the insulating film has a stacked structure in which a low dielectric insulating film is interleaved in a silicon dioxide film, the low dielectric insulating film being of etching characteristics different from those of the silicon dioxide film,
wherein the low dielectric insulating film is interleaved in a region where bowing occurs when the deep hole is formed only in the silicon dioxide film using the dry etching carried out in a prescribed condition, and
wherein upon the etching of the silicon dioxide film in the prescribed condition, an etching rate of the low dielectric insulating film is slower than that of the silicon dioxide film.

2. The method of claim 1, wherein the etching rate of the low dielectric insulating film in the prescribed condition has a range of ⅕ to 1/10 times the etching rate of the silicon dioxide film.

3. The method of claim 1, wherein the low dielectric insulating film is formed from a silicon oxycarbide film.

4. The method of claim 3, wherein the dry etching of the insulating film includes dry etching of the silicon dioxide film in the prescribed condition, and dry etching of the silicon oxycarbide film in the condition in which the etching rate thereof equals to the etching rate of the silicon dioxide film.

5. The method of claim 4, wherein the dry etching of the silicon oxycarbide film is carried out in the condition in which the etching gas contains at least one of N₂, CHF₃, and CH₂F₂.

6. The method of claim 3, comprising forming, on the insulating film, a hard mask having a stacked structure including an amorphous carbon film and an anti-reflection layer, wherein the silicon oxycarbide film is isolated from the amorphous carbon film.

7. The method of claim 1, wherein the deep hole is a cylinder hole forming a cylindrical electrode.

8. The method of claim 7, wherein comprising forming, in the cylinder hole, the cylindrical electrode serving as a capacitor lower electrode, and forming a capacitor dielectric and an upper electrode on the insulating film and on an inner surface of the cylindrical electrode, respectively.

9. The method of claim 7, comprising forming, in the cylinder hole, the cylindrical electrode serving as a capacitor lower electrode, and removing the insulating film, and forming a capacitor dielectric and an upper electrode on inner and outer surfaces of the cylindrical electrode that are exposed.

10. The method of claim 9, wherein the semiconductor device includes a memory array area in which the capacitor is formed and a peripheral circuit area in which a peripheral circuit is formed, and in at least the peripheral circuit area, the stacked structure in which the low dielectric insulating film is interleaved in the silicon dioxide film is left as an interlayer insulating film.
